(19) United States
(12) Patent Application Publication
(10) Pub. No.: US 2012/0235245 A1
(43) Pub. Date: Sep. 20, 2012

(54) SUPERIOR INTEGRITY OF HIGH-K METAL GATE STACKS BY REDUCING STI DIVOTS BY DEPOSITING A FILL MATERIAL AFTER STI FORMATION

(75) Inventors: Rohit Pal, Dresden (DE); Stephan-Detlef Kronholz, Dresden (DE)

(73) Assignee: GLOBALFOUNDRIES INC., Grand Cayman (KY)

(21) Appl. No.: 13/422,148

(22) Filed: Mar. 16, 2012

(30) Foreign Application Priority Data
Mar. 17, 2011 (DE) 10 2011 005 719.6

(51) Int. Cl. H01L 27/088; H01L 21/762; H01L 21/336

(52) U.S. Cl. 257/368; 438/296; 438/424; 257/E27.06; 257/E21.409; 257/E21.546

(57) ABSTRACT

When forming sophisticated semiconductor devices on the basis of high-k metal gate electrode structures, which are to be provided in an early manufacturing stage, the encapsulation of the sensitive gate materials may be improved by reducing the depth of or eliminating recessed areas that are obtained after forming sophisticated trench isolation regions. To this end, after completing the STI module, an additional fill material may be provided so as to obtain the desired surface topography and also preserve superior material characteristics of the trench isolation regions.

### BACKGROUND OF THE INVENTION

1. Field of the Invention

Generally, the present disclosure relates to the fabrication of highly sophisticated integrated circuits including advanced transistor elements that comprise gate structures of increased capacitance including a high-k gate dielectric material.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout. In a wide variety of integrated circuits, field effect transistors represent one important type of circuit element that substantially determines performance of the integrated circuits. Generally, a plurality of process technologies are currently practiced for forming field effect transistors, wherein, for many types of complex circuitry, CMOS technology is one of the most promising approaches due to the superior characteristics in view of operating speed and/or power consumption and/or cost efficiency. During the fabrication of complex integrated circuits using CMOS technology, millions of transistors, i.e., N-channel transistors and P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the mobility of the charge carriers in the channel region.

The continuous shrinkage of critical dimensions of transistor elements has resulted in a gate length of field effect transistors of 50 nm and significantly less, thereby providing sophisticated semiconductor devices having enhanced performance and an increased packing density. The increase of electrical performance of the transistors is strongly correlated with a reduction of the channel length, which may result in an increased drive current and switching speed of the field effect transistors. On the other hand, the reduction of the channel length is associated with a plurality of tissues in terms of channel controllability and static leakage currents of these transistors. It is well known that field effect transistors with a very short channel may require an increased capacitive coupling between the gate electrode structure and the channel region in order to provide the desired static and dynamic current flow controllability. Typically, the capacitive coupling is increased by reducing the thickness of the gate dielectric material, which is typically formed on the basis of a silicon dioxide-based material, possibly in combination with a nitrogen species, due to the superior characteristics of a silicon/silicon dioxide interface. Upon implementing a channel length of the above-identified order of magnitude, however, the thickness of the silicon dioxide-based gate dielectric material may reach values of 1.5 nm and less, which in turn may result in significant leakage currents due to a direct tunneling of the charge carriers through the very thin gate dielectric material. Since the exponential increase of the leakage currents upon further reducing the thickness of silicon dioxide-based gate dielectric materials is not compatible with the thermal power design requirements, other mechanisms have been developed so as to further enhance transistor performance and/or reduce the overall transistor dimensions.

For example, by creating a certain strain component in the channel region of silicon-based transistor elements, the charge carrier mobility and, thus, the overall conductivity of the channel may be enhanced. For a silicon material with a standard crystallographic configuration, i.e., a (100) surface orientation with the channel length direction oriented along a <110> equivalent direction, tensile strain in the current flow direction may enhance conductivity of electrons, thereby improving transistor performance of N-channel transistors. On the other hand, generating a compressive strain in the current flow direction may increase the mobility of holes and may, thus, provide superior conductivity in P-channel transistors. Consequently, a plurality of strain-inducing mechanisms have been developed in the past, which per se require a complex manufacturing sequence for implementing these techniques. Upon further device scaling, “internal” strain-inducing sources, such as an embedded strain-inducing semiconductor material, may represent a very efficient strain-inducing mechanism. For example, frequently the incorporation of a compressive strain-inducing silicon/germanium alloy in the drain and source areas of P-channel transistors is applied in order to enhance performance of these transistors. For this purpose, in an early manufacturing stage, cavities are formed in the active region laterally adjacent to the gate electrode structure of the P-channel transistor, while the N-channel transistors are covered by a spacer layer. These cavities may be subsequently refilled with the silicon/germanium alloy on the basis of selective epitaxial growth techniques. During the etch process for forming the cavities and during the subsequent epitaxial growth process, the gate electrode of the P-channel transistor has to be encapsulated in order to not unduly expose sensitive materials of the gate electrode structure, such as a silicon-based electrode material, to the process ambient for forming the cavities and for selectively growing the silicon/germanium alloy. Thereafter, the gate electrode structures may be exposed and the further processing may be continued by forming drain and source regions in accordance with any appropriate process strategy.

Basically, the above-described strain-inducing mechanism is a very efficient concept for improving transistor performance of P-channel transistors, wherein the efficiency of the finally obtained strain in the channel region of the transistor, however, strongly depends on the internal strain level of the semiconductor alloy and on the lateral offset of this material from the channel region. Typically, the material composition of the strain-inducing semiconductor alloy is restricted by currently available sophisticated selective epitaxial deposition recipes, which in the case of a silicon/germanium alloy may presently not allow germanium concentrations of more than approximately 30 atomic percent. Consequently, a further improvement of the total strain in the channel region requires a reduction of the lateral offset of the silicon/germanium alloy from the channel region so that any protective spacer structures may have to be provided with a reduced width.

In addition to providing strain-inducing mechanisms in sophisticated field effect transistors, also sophisticated gate electrode materials have been proposed in order to overcome the restrictions of conventional silicon dioxide/polysilicon-based gate electrode structures. To this end, the conventional silicon dioxide-based gate dielectric material is replaced, at least partially, by a so-called high-k dielectric material, i.e., a dielectric material having a dielectric constant of 10.0 and higher, which may result in a desired high capacitance between the gate electrode and the channel region, while nevertheless a certain minimum physical thickness is provided so as to keep the resulting leakage currents at an acceptable level. For this purpose, a plurality of dielectric materials, such as hafnium oxide-based materials, zirconium oxide, aluminum oxide and the like, are available and may be used in sophisticated gate electrode structures. Furthermore, the polysilicon material may also be replaced, at least in the vicinity of the gate dielectric material, since typically polysilicon suffers from charge carrier depletion in the vicinity of the gate dielectric material, which may reduce the effective capacitance. Moreover, with sophisticated high-k gate dielectric materials, the work function of standard polysilicon materials and a corresponding doping may no longer be sufficient to provide the required electronic characteristics of the gate electrode material in order to obtain a desired threshold voltage of the transistors under consideration. For this reason, specific work function adjusting metal species, such as aluminum, lanthanum and the like, are typically incorporated in the gate dielectric material and/or in an appropriate electrode material in order to obtain a desired work function and also increase conductivity of the gate electrode material at least in the vicinity of the gate dielectric material.

Thus, a plurality of sophisticated process strategies have been developed, wherein, in some promising approaches, the sophisticated gate materials, such as a high-k dielectric material and a metal-containing electrode material, possibly including a work function adjusting metal species, may be provided in an early manufacturing stage in combination with a polysilicon material, thereby providing a high degree of compatibility with conventional process strategies for forming sophisticated field effect transistors. It turns out, however, that a reliable confinement of the sensitive material system including the high-k dielectric material and the metal-containing electrode material has to be guaranteed in order to avoid a shift in threshold voltage or any other variabilities of the sophisticated high-k metal gate electrode structures.

In an attempt to further enhance device performance of sophisticated field effect transistors, it has been proposed to combine sophisticated high-k metal gate electrode structures with a strain-inducing mechanism, for instance, by incorporating a strain-inducing semiconductor alloy in the active regions of the transistors. In this case, the encapsulation of the gate electrode structure of the transistor, which may require the incorporation of an embedded strain-inducing semiconductor alloy, may have to be implemented on the basis of detrimental requirements. On the one hand, the confinement of the gate electrode structure has to ensure integrity of the sensitive material system, for example, prior to, during and after the incorporation of the strain-inducing semiconductor material, and, on the other hand, a reduced thickness of any protective spacer elements, such as silicon nitride-based materials, is to be selected with reduced width in view of enhancing efficiency of the strain-inducing mechanism. Consequently, a compromise of thickness of the spacer elements and gain in performance of sophisticated transistors is typically applied.

In many conventional approaches, however, overall defectivity during the patterning of the sophisticated high-k metal gate electrode structures may require efficient wet chemical cleaning processes. For this purpose, an SPM (mixture of sulfuric acid and hydrogen peroxide) solution has proven to be a very efficient cleaning agent, which, however, “efficiently” removes metal-containing electrode materials, such as titanium nitride, as are provided in the sophisticated gate electrode structure. Omitting the cleaning step on the basis of SPM or providing a less efficient cleaning recipe may significantly increase the overall defectivity, thereby resulting in a significant yield loss. Using efficient SPM cleaning solutions, however, may result in significant gate failures in sophisticated semiconductor designs, as will be described in more detail with reference to FIGS. 1a-1f.

FIG. 1a schematically illustrates a top view of a semiconductor device 100 according to a complex design. As shown, the device 100 or its design comprises an active region 102A, which is to be understood as a semiconductor region in which one or more transistors are to be formed. For example, the active region 102A is illustrated to comprise three transistors 150A including respective gate electrode structures 130A. The gate electrode structures 130A may include a complex material system including a high-k dielectric material and a metal-containing electrode material, as discussed above. Basically, the gate electrode structures 130A represent conductive lines extending across the active region 102A and are typically formed with an end portion thereof on an isolation region 102C, which laterally delineates the active region 102A and any other active regions (not shown). Moreover, according to design requirements, a gate electrode structure 130C may also extend above the isolation region 102C in close proximity to the active region 102A. It should be appreciated that a length of the gate electrode structures 130A, 130C may be 50 nm and less in sophisticated applications so that the distance between the gate electrode structure 130C and the active region 102A may be significantly less than the critical gate length. Furthermore, the transistors 150A may represent devices that require the incorporation of a strain-inducing semiconductor material, such as a silicon/germanium alloy, possibly in combination with a semiconductor alloy for appropriately adjusting the threshold voltage of the transistors 150A.

Consequently, upon forming the device 100 according to the geometric configuration as shown in FIG. 1a, a plurality of complex process steps are required for forming the isolation region 102C and the active region 102A, followed by a sophisticated patterning process for implementing the gate electrode structures 130A, 130C in combination with any processes for forming the semiconductor alloy as required for adjusting the threshold voltage of the transistors 150A. To this end, complex wet chemical cleaning recipes are typically applied, which may have a negative influence on the finally obtained device characteristics, which may even result in significant gate failures. For example, it has been observed that, in particular, the metal-containing electrode material of the sensitive material system in the gate electrode structures 130A, 130C is significantly damaged or missing, which may result in reduced performance or total failure of the corresponding transistor elements. For this reason, appropriate sidewall spacer structures or protective liners are provided immediately after patterning the gate electrode structures 130A, 130C in order to appropriately encapsulate the sensitive gate material system. Although this concept may significantly reduce the gate failures, nevertheless, advanced yield loss may occur, wherein it has been recognized that, in particular, critical areas 100C significantly contribute to any device failures. For example, one of the critical regions 100C is a gate electrode structure or gate line 130C that is positioned close to the active region 102A. Moreover, the end portions of the gate electrode structures 130A, which extend from the active region 102A into the isolation region 102C also represent critical zones in which inferior integrity of the sensitive gate materials is observed. It is believed that, in particular, a significant recessing of the isolation region 102C in the vicinity of the active region 102A contributes to a less efficient encapsulation of the gate electrode structures 130A, 130C, which may then result in significant yield loss during the further processing, as will be described in more detail with reference to FIGS. 1b-1f.

FIG. 1b schematically illustrates a cross-sectional view of a semiconductor device 100 according to the section indicated as Ib in FIG. 1a. As illustrated, the device 100 comprises a substrate 101 and a semiconductor layer 102, which is typically provided in the form of a silicon material. The substrate 101 and the semiconductor layer 102 may form a silicon-on-insulator (SOI) architecture when a buried insulating material (not shown) is formed below the semiconductor layer 102. In other cases, a bulk configuration may be formed by the semiconductor layer 102 and the substrate 101, when the semiconductor layer 102 is a portion of a crystalline semiconductor material of the substrate 101. The semiconductor layer 102 typically comprises a plurality of active regions, such as the active region 102A, which are laterally delineated by the isolation region 102C. The isolation region 102C is typically comprised of silicon dioxide and may have a pronounced recessing 102R that is positioned close to the active region 102A. Furthermore, the gate electrode structures 130A, 130C are formed on the active region 102A and the isolation region 102C, respectively, and comprise a material system 131, which is to be understood as a gate dielectric material including a high-k dielectric material, such as hafnium oxide and the like, in combination with a conventional dielectric material, such as silicon oxynitride and the like. Moreover, typically, the material system 131 comprises a metal-containing cap or electrode material, such as titanium nitride, which may also include appropriate metal species in order to obtain the desired work function, as is also discussed above. Thus, the material system 131 typically comprises a plurality of individual material layers, wherein the specific number and composition of the various material layers depends on device and process requirements. Furthermore, the gate electrode structures 130A, 130C comprise a further electrode material 132, for instance in the form of a silicon material, followed by a dielectric cap material 133, such as a silicon nitride material, a silicon dioxide material or a combination thereof and the like. Furthermore, a liner or spacer 134, for instance comprised of silicon nitride, is formed on the sidewalls of the materials 132 and 131 in order that in particular any sensitive materials in the system 131 are appropriately protected.

FIG. 1c schematically illustrates a cross-sectional view along the section Ic of FIG. 1a. Thus, as shown, the gate electrode structure 130A is formed above the active region 102A and extends with an end portion thereof into the isolation region 102C. Also in this area the pronounced recess 102R is typically present and may have a significant influence on the final characteristics of the gate electrode structure 130A.

The semiconductor device 100 as shown in FIGS. 1b and 1c is formed on the basis of the following process techniques. The isolation region 102C is formed in the semiconductor layer 102 on the basis of well-established shallow trench isolation process techniques. Thereafter, appropriate masking regimes may be applied so as to incorporate a desired well dopant species in the various active regions, such as the active region 102A, thereby adjusting the basic transistor characteristics, such as conductivity type, threshold voltage and the like. As is well known, a plurality of cleaning processes may typically have to be applied which may result in a certain degree of material erosion in the isolation region 102C, wherein additional rework processes of the lithography processes may even further contribute to unwanted material erosion. Moreover, as discussed above, in some active regions, an additional semiconductor material (not shown) is frequently provided on the basis of selective epitaxial growth techniques, for instance for appropriately adjusting the threshold voltage of P-channel transistors, wherein the corresponding masking process in combination with the selective epitaxial growth techniques and the surface preparation processes associated therewith may result in a pronounced material loss in the isolation region 102C, in particular in the vicinity of the active region 102A when corresponding to a P-channel transistor. Thereafter, the further processing is continued by providing material layers for the system 131, possibly in combination with additional heat treatments so as to diffuse a work function adjusting metal species and the like. Finally, the material 132 and the cap material 133, possibly in combination with additional sacrificial materials, such as hard mask materials and the like, are deposited on the basis of appropriate process techniques. It should be appreciated that providing appropriate work function metals for P-channel transistors and N-channel transistors, respectively, may also involve respective patterning processes. Next, the complex layer stack is patterned by using sophisticated lithography and etch techniques followed by the deposition of a spacer layer or liner, which is subsequently patterned into the liner or spacer structure 134. To this end, various process strategies may be applied wherein, in other device areas, the spacer or liner material may be patterned in a later manufacturing stage, while in other cases a dedicated liner material may be formed and patterned prior to depositing the spacer material, which may be used for forming the structure 134.

With reference to FIGS. 1d-1f, a process sequence will be described as an example for illustrating a failure mechanism, in which the encapsulation of the gate electrode structures, such as the gate electrode structure 130C (FIG. 1b), may be insufficient and may result in pronounced yield loss. It should be appreciated, however, that a similar exposure of sensitive gate materials may also occur at the end portions of the gate electrode structure 130A caused by the pronounced recessing 102R, as shown in FIG. 1c.

FIG. 1d schematically illustrates the device 100 during an etch process 103 for forming cavities 103A in the active region 102A adjacent to the isolation region 102C. As illustrated, the cap materials 133 and the liner 134 may act as an etch mask.

FIG. 1e schematically illustrates the device 100 during a cleaning process 104 in order to remove any etch byproducts and other contaminants, thereby, however, also contributing to a certain material erosion at exposed sidewall surface areas in the cavities 103A.

FIG. 1f schematically illustrates the semiconductor device 100 during a further cleaning process 106, which is typically performed prior to starting a selective epitaxial growth process in order to remove native oxides and the like. On the other hand, a certain degree of material erosion may occur in the cavities 103A so that a sidewall surface area 131S of the sensitive material system 131 may be exposed below the sidewall spacer structure 134 of the gate electrode structure 130C. Consequently, sensitive materials may be attacked and may be removed, depending on the cleaning or etch chemistry used. Furthermore, during the further processing, for instance upon epitaxially growing a strain-inducing semiconductor alloy in the cavities 103A, the sidewalls may not be efficiently covered, thereby even further contributing to material deterioration of the system 131 during the further processing.

Similarly, the recessed configuration of the isolation region 102C at or near the end portions of the gate electrode structure 130C may also result in an exposure of any sensitive materials, thereby causing a significant shift of the overall material characteristics.

In view of the situation described above, the present disclosure relates to manufacturing techniques and semiconductor devices in which sophisticated high-k metal gate electrode structures may be formed in an early manufacturing stage, while avoiding or at least reducing the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques and semiconductor devices in which recessed areas or divots in sophisticated trench isolation regions may be reduced in depth or may be substantially completely filled after completing the trench isolation process. To this end, an appropriate fill material may be locally provided in the recessed area, thereby achieving an improved surface topography for the further processing of the device. Consequently, critical process steps, such as the encapsulation of sophisticated high-k metal gate electrode structures, may be accomplished, thereby significantly improving overall production yield and device uniformity due to a significant reduction of gate failures or a shift of transistor characteristics. In some illustrative embodiments disclosed herein, the fill material may be provided on the basis of a high quality silicon oxide material, which may be efficiently incorporated into the recessed areas by a deposition process, while the final material characteristics may be established on the basis of a subsequent anneal process. Hence, well-established process techniques may be applied for forming sophisticated trench isolation regions, while nevertheless enhanced process robustness in subsequent critical process steps may be achieved.

One illustrative method disclosed herein comprises forming a trench isolation region in a semiconductor layer of a semiconductor device, wherein the trench isolation region laterally delineates an active region in the semiconductor layer. The method further comprises forming a fill material selectively in a recessed area of the trench isolation region. Moreover, the method comprises forming a gate electrode structure on the active region and the trench isolation region that includes the fill material.

A further illustrative method disclosed herein comprises forming a trench isolation region in a semiconductor layer of a semiconductor device so as to laterally delineate an active region, wherein the trench isolation region comprises a recessed area adjacent to the active region. The method further comprises reducing a depth of the recessed area of the trench isolation region and forming a gate electrode structure on the trench isolation region, wherein the gate electrode structure comprises a high-k dielectric material.

One illustrative semiconductor device disclosed herein comprises a trench isolation region that laterally delineates an active region in a semiconductor layer. The trench isolation region comprises a first dielectric material and a second dielectric material that is locally formed adjacent to the active region. The semiconductor device further comprises a gate electrode structure formed on a channel area of the active region, wherein the gate electrode structure comprises a material system comprising a high-k dielectric material and a metal-containing electrode material. The gate electrode structure further comprises a protective liner formed on sidewalls of the high-k dielectric material and the metal-containing electrode material.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a top view of a semiconductor device wherein a high-k metal gate electrode structure is formed on the basis of a conventional process strategy with recessed areas formed on edge areas of trench isolation regions adjacent to active regions;

FIGS. 1b-1f schematically illustrate cross-sectional views of the semiconductor device during various manufacturing stages in which an encapsulation of the high-k metal gate electrode structure is performed on the basis of the recessed areas in the trench isolation regions, thereby causing significant yield loss;

FIGS. 2a-2d schematically illustrate cross-sectional views of a semiconductor device during various manufacturing stages after completing a trench isolation region based on well-established process techniques, wherein any divots or recessed areas adjacent to any active regions may be reduced in depth or may be substantially completely filled with an appropriate fill material, according to illustrative embodiments;

FIGS. 2e-2f schematically illustrate cross-sectional views of the semiconductor device according to further illustrative embodiments in which a fill material may be provided on the basis of an etch stop liner so as to provide superior process control and integrity of active regions; and

FIGS. 2g-2h schematically illustrate cross-sectional views of the semiconductor device in further advanced manufacturing stages in which sophisticated high-k metal gate electrode structures may be reliably encapsulated on the basis of the superior surface topography of the trench isolation regions, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally contemplates manufacturing techniques and semiconductor devices in which the problem of gate failures or significant shifts in transistor characteristics may be addressed by reducing the surface topography of trench isolation regions prior to forming sophisticated gate electrode structures. As discussed above, typically, sophisticated lithography and etch strategies have to be applied in forming an appropriate hard mask material and etching into the semiconductor material in order to define the lateral size, position and shape of the trench isolation regions. Thereafter, complex deposition processes and anneal sequences are applied and any excess materials are removed together with the hard mask material or materials, thereby producing a surface topography in which pronounced recessed areas are formed adjacent to the active regions. These recessed areas or divots may significantly influence the further processing of the device, as is, for instance, described above with reference to the semiconductor device 100. Due to the significant yield loss, which is believed to be caused by the presence of the recessed areas, great efforts have been made in order to avoid the creation of the recessed areas upon forming the trench isolation regions. It turns out, however, that many of these approaches may require different dielectric materials to be used, while in other cases highly complex process modifications may have to be implemented, thereby contributing to increased process complexity, while also the compatibility with subsequent process techniques may not be ensured for at least some of such approaches. According to the principles disclosed herein, however, well-established material characteristics and manufacturing techniques used for forming sophisticated trench isolation regions may be preserved, while on the other hand the surface topography may be significantly reduced in a subsequent process sequence by reducing the depth of the recessed areas, while at the same time desired material characteristics of the trench isolation regions are achieved. To this end, in some illustrative embodiments, an appropriate fill material, for instance a silicon oxide material, may be efficiently deposited into the recessed areas and may be densified so as to obtain similar material characteristics compared to the actual dielectric material of the trench isolation regions obtained after completing the trench formation module.

In other illustrative embodiments, superior process control upon removing any excess portion of the additional fill material may be achieved by providing a stop liner, which may be used to control a removal process, such as a chemical mechanical polishing (CMP) process, thereby avoiding undue recessing of the additional fill material. On the other hand, the stop liner may be efficiently removed by highly selective wet chemical etch recipes substantially without affecting the previously formed fill material. Also in this manner, the fill material may be provided with the desired material composition, for instance substantially with the same stoichiometric composition compared to the actual fill material of the trench isolation region, while the presence of the stop material in the recessed areas of the trench isolation region may not negatively influence the overall device characteristics.

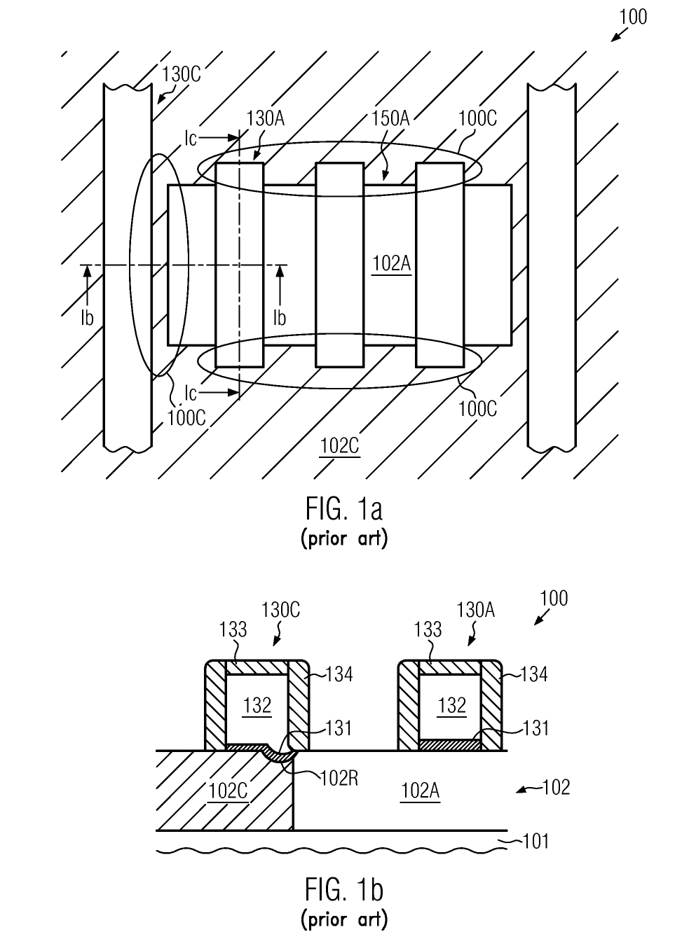

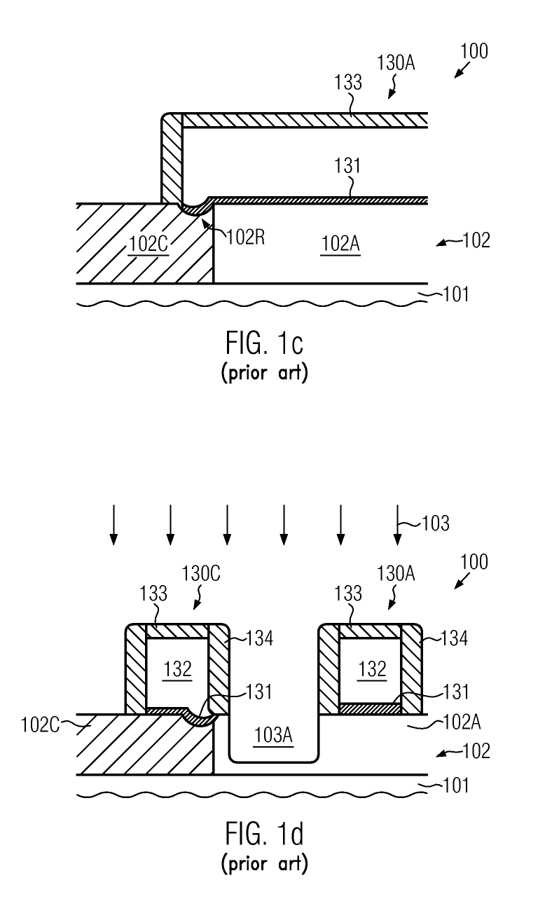

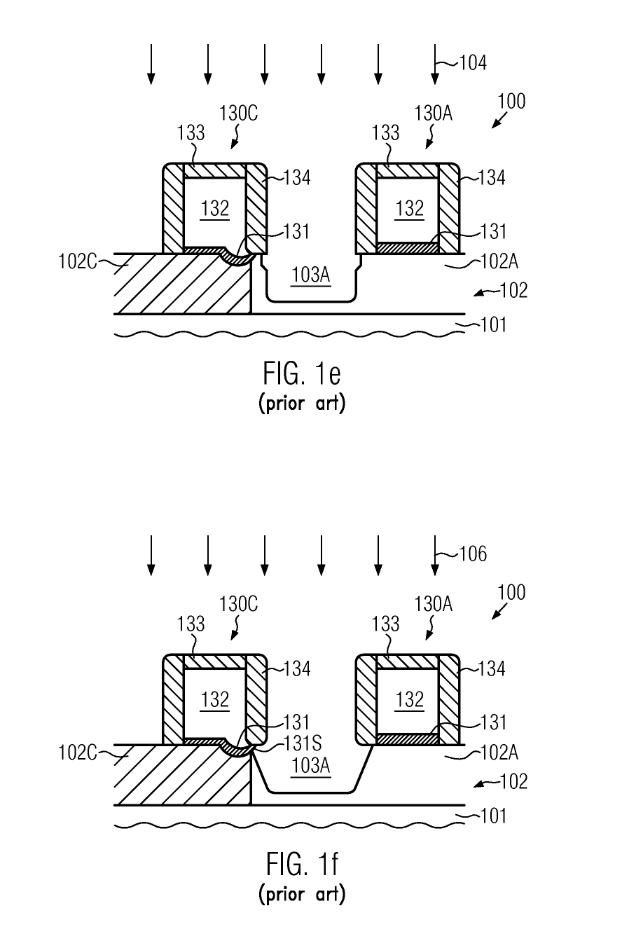

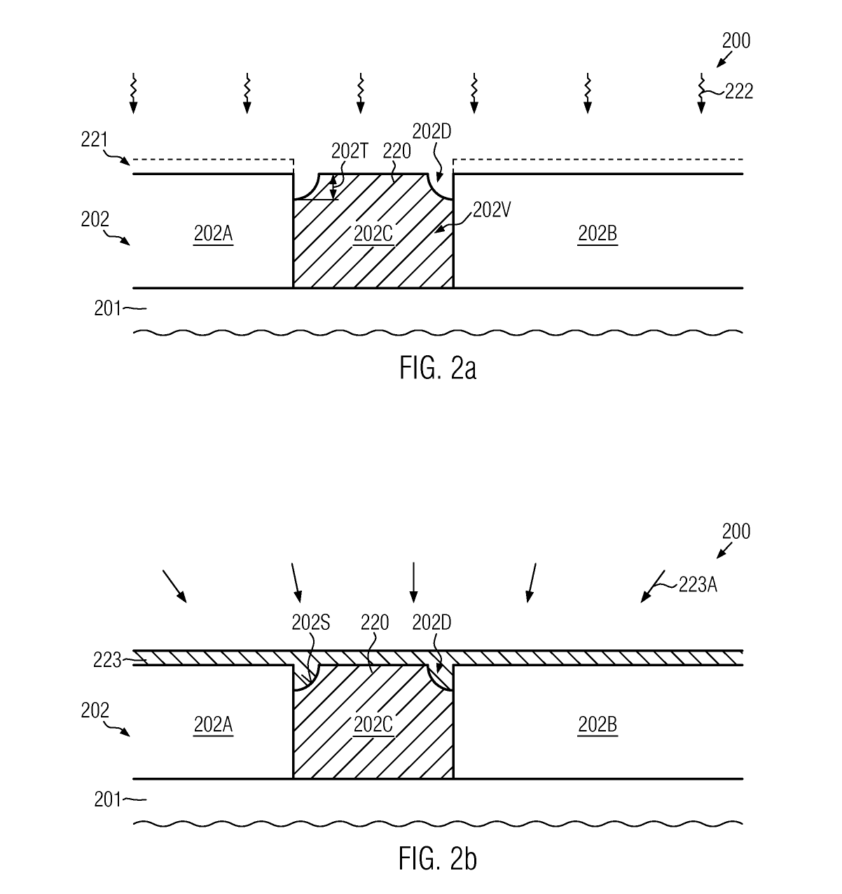

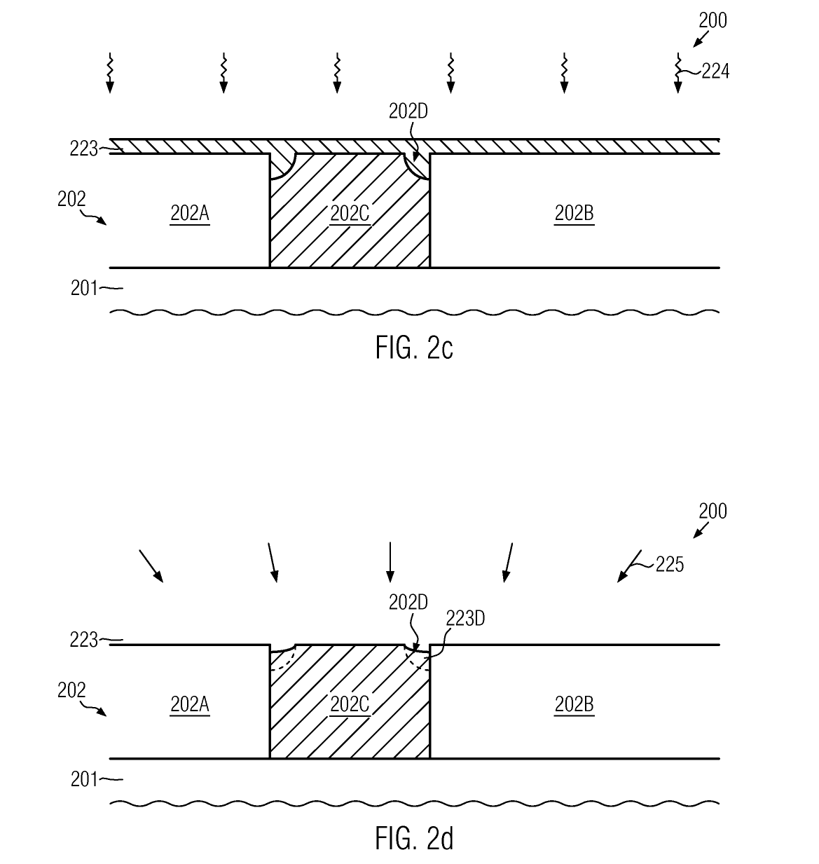

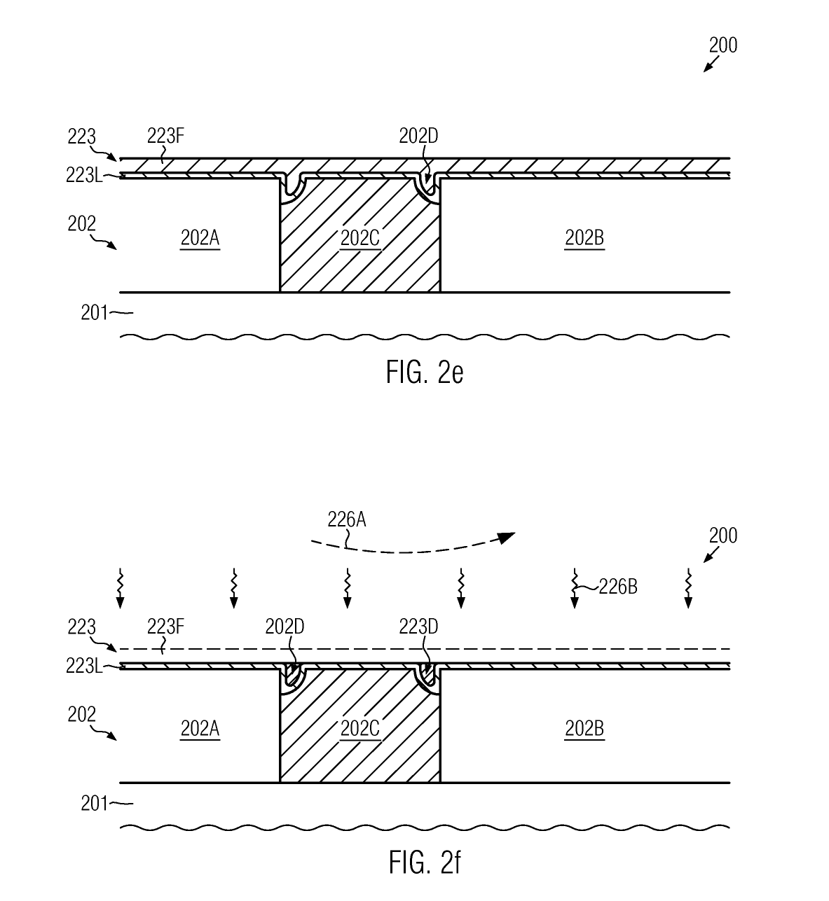

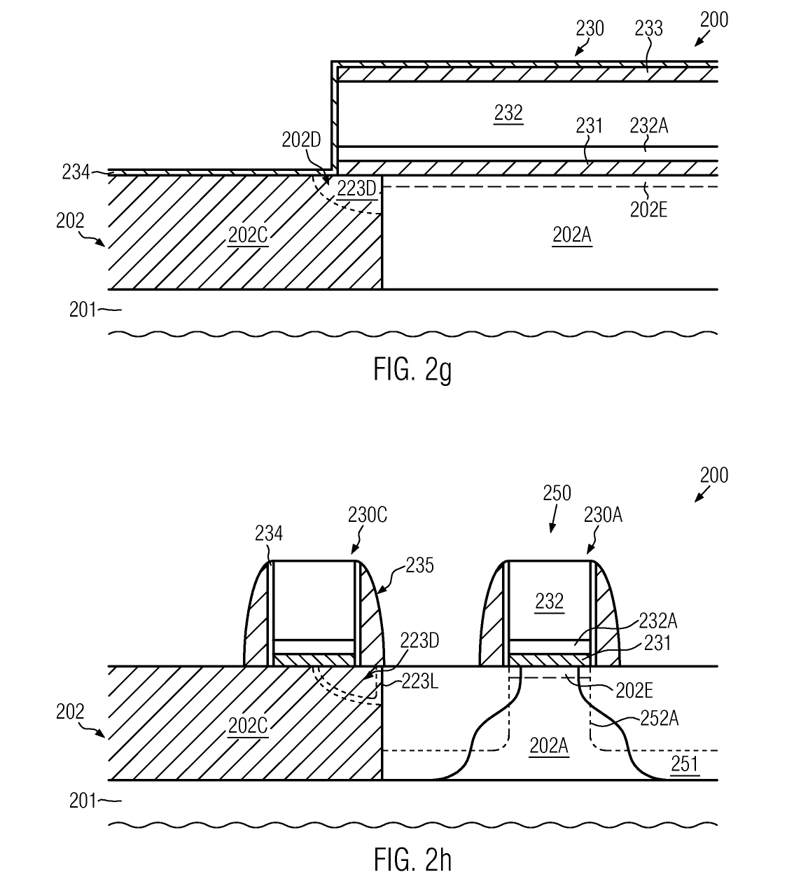

With reference to FIGS. 2a-2h, further illustrative embodiments will now be described in more detail, wherein reference may also be made to FIGS. 1a-1f, if appropriate.

FIG. 2a schematically illustrates a cross-sectional view of a semiconductor device 200 in a manufacturing stage in which a trench isolation region may be provided in a semiconductor layer. As shown, the device 200 may comprise a substrate 201 and a semiconductor layer 202 which, as also discussed above with reference to the semiconductor device 100, may form an SOI configuration when a buried insulating material is formed below the semiconductor layer 202, or which may form a bulk configuration when the semiconductor layer 202 is directly in contact with a crystalline semiconductor material of the substrate 201. Furthermore, a trench isolation region 202C laterally delineates active regions 202A, 202B, thereby appropriately defining the position, the lateral size and shape of the active regions 202A, 202B. The isolation region 202C may comprise any appropriate dielectric material 220, such as a silicon oxide material, having an appropriate density and thus a moderately high etch resistivity during the further processing of the device 200. As previously discussed, the trench isolation region 202C may comprise divots or recessed areas 202D in the vicinity of the active regions 202A, 202B.

The device 200 as shown in FIG. 2a may be formed on the basis of well-established shallow trench isolation (STI) techniques, which include the provision of a hard mask material 221, for instance in the form of a silicon dioxide layer in combination with a silicon nitride material, which may be subsequently patterned on the basis of sophisticated lithography techniques. Thereafter, a trench 202V may be formed by appropriate etch techniques and subsequently the dielectric material 220 may be filled into the trench 202V, for instance on the basis of high density plasma chemical vapor deposition (CVD) recipes, wherein frequently a sequence of deposition and etch steps may be applied so as to obtain a desired degree of bottom to top fill behavior. Thereafter, the dielectric material 220 may be annealed, as indicated by 222, in order to densify the material and thus increase its etch resistivity. Thereafter, any excess portion may be removed, for instance by CMP, and the hard mask material 221 may be used as a stop material. Thereafter, the hard mask material 221 may be removed by etch processes and the like. At the end of the previously described complex process sequence, the recessed areas 202D are typically present with a depth 202T, which may be several nanometers to several tenths of nanometers and which may have a significant influence on the further processing, as discussed above.

FIG. 2b schematically illustrates the device 200 in a further advanced manufacturing stage. As shown, a deposition process 223A may be performed so as to deposit a cap layer 223, which may substantially completely fill the recessed areas 202D, while also forming a substantially uniform layer on top of any horizontal device areas. The deposition process 223A may be performed on the basis of CVD techniques, wherein the material growth on the various sidewalls of the recessed areas 202D, indicated as 202S, may result in a substantially complete filling of the areas 202D, since, for a given thickness of the layer 223, the growth of the material on the sidewalls 202S may result in a “merging” of corresponding “overhangs,” thereby reliably closing the areas 202D. In some illustrative embodiments, the cap layer 223 may be formed on the basis of a material that may have substantially the same stoichiometric composition as the dielectric material 220. For example, well-established CVD recipes are available for forming a silicon oxide material.

FIG. 2c schematically illustrates the device 200 in a further advanced manufacturing stage in which the cap layer 223 may be exposed to elevated temperatures in the form of an anneal process 224 in order to improve the overall material characteristics of the cap layer 223. To this end, in some illustrative embodiments, a process atmosphere may be established on the basis of oxygen and/or nitrogen with temperatures in the range of 800-1100° C., thereby inducing a desired densification of the material 223, when provided in the form of a silicon oxide material, which may result in material characteristics that are very similar to the material characteristics of a thermally grown silicon oxide material. Consequently, during the corresponding reduction in volume, also the material in the recessed areas 202D is appropriately densified, thereby endowing these areas with superior surface topography and enhanced etch resistivity during the further processing. In other illustrative embodiments, the anneal process 224 may be performed on the basis of a plasma, which may enable the use of lower temperatures while also achieving the desired densification of the material of the cap layer 223. For example, a plurality of plasma-based anneal techniques are available. For instance, anneal processes on the basis of uniform and highly controllable plasma conditions may be used with temperatures in the range of 300-700° C. It should be appreciated, however, that other process parameters may be readily selected by performing corresponding experiments in order to determine appropriate process parameters that may result in the desired material characteristics of the cap layer 223 prior to removing an excess portion thereof.

FIG. 2d schematically illustrates the device 200 during an etch process 225 in which an excess portion of the cap layer 223 (FIG. 2c) may be removed, i.e., the active regions 202A, 202B may be exposed and may thus be prepared for the further processing of the device 200. In some illustrative embodiments, the etch process 225 may be performed on the basis of hydrofluoric acid (HF), which may efficiently remove silicon oxide material selectively with respect to silicon material. Due to the previously applied anneal process 224 (FIG. 2c), superior etch resistivity of the dielectric material may be obtained, thereby ensuring a highly controllable advance of the etch process 225. Moreover, due to the highly uniform configuration of the cap layer 223 (FIG. 2c), an undue over-etch time may not be required so that a fill material 223D in the recessed areas 202D may be substantially preserved after completing the etch process 225. Hence, the resulting surface topography may be significantly improved compared to the initial trench isolation region 202C (FIG. 2a), wherein even a substantially complete filling of the recessed areas 202D may be achieved by appropriately controlling the deposition of the cap layer 223 (FIG. 2c) and the etch process 225.

Consequently, based on the trench isolation region 202C as shown in FIG. 2d, the further processing may be continued by forming gate electrode structures wherein the superior surface topography in the initially recessed areas 202D may provide enhanced process conditions, in particular with respect to the encapsulation of the critical gate electrode structures.

FIG. 2e schematically illustrates the device 200 according to further illustrative embodiments. As shown, the cap layer 223 may be formed above the active regions 202A, 202B and above the trench isolation region 202C, which comprises initially the recessed areas 202D, as discussed above. In the embodiment shown, the cap layer 223 may comprise a stop liner 223L, for instance provided on the basis of a silicon nitride material, which may be provided with a thickness of one to several nanometers, depending on the overall process and device requirements. To this end, well-established highly conformal deposition recipes may be applied, such as multi-layer deposition, low pressure CVD techniques and the like, in which thin silicon nitride materials may be formed in a highly controllable manner. Consequently, any exposed surface areas and in particular the surface of the active regions 202A, 202B may be covered or masked by the stop liner 223L. Thereafter, the desired fill material 223F may be formed, for instance by corresponding deposition techniques, as described above, thereby completely filling the recessed areas 202D and providing a continuous layer above the active regions 202A, 202B and the isolation region 202C. Thereafter, if required, an anneal process may be applied, for instance as described above, in order to further densify, in particular, the fill material 223F, while in other cases the further processing may be continued without applying an anneal process.

FIG. 2f schematically illustrates the device 200 in a further advanced manufacturing stage. As illustrated, a material removal process 226A may be applied so as to remove an excess portion of the fill material 223F. In some illustrative embodiments, the process 226A may be performed on the basis of CMP techniques, thereby efficiently removing material of the layer 223F, while on the other hand the stop liner 223L may be used for controlling the process 226A. For example, silicon oxide material may be efficiently removed selectively with respect to silicon nitride material on the basis of a plurality of well-established CMP recipes. Hence, the fill material 223D, i.e., the remaining portion of the previously provided fill material 223F, may be preserved in the areas 202D, wherein, in particular, the local restriction of the recessed areas 202D to the immediate neighborhood of the active regions 202A, 202B may not result in significant “dishing” effects so that the recessed areas 202D may remain substantially filled with the material 223D after the removal process 226A. Thereafter, a further material removal process 226B may be applied, for instance in the form of a highly selective wet chemical etch process, for instance using hot phosphoric acid and the like, thereby efficiently etching the liner 223L without unduly affecting the active regions 202A, 202B and without unduly affecting the fill material 223D in the recessed areas 202D.

Consequently, also in this case, the further processing may be continued on the basis of a superior surface topography of the trench isolation region 202C, while on the other hand increased process flexibility may be achieved by providing the stop liner 223L.

FIG. 2g schematically illustrates the semiconductor device 200 in a further advanced manufacturing stage. As illustrated, a gate electrode structure 230 may be formed above the active region 202A and may also extend above a portion of the isolation region 202C, for instance in a similar configuration as previously described with reference to FIGS. 1a and 1c. As shown, the gate electrode structure 230 may comprise a gate dielectric material 231 and an electrode material 232, which may be covered by a dielectric cap layer or cap layer system 233, as is also previously discussed. In some illustrative embodiments, the dielectric material 231 may comprise or may represent a high-k dielectric material in order to enhance overall performance of a transistor to be formed on the basis of a gate electrode structure 230, as discussed above. Furthermore, in this case, an additional electrode material 232A may be provided on or above the gate dielectric material 231 and may have any appropriate composition that ensures the desired work function value and thus threshold voltage for a transistor to be formed in and above the active region 202A. Furthermore, the very sensitive materials 231, 232A may be laterally encapsulated by a protective liner 234, such as a silicon nitride material, wherein the encapsulation may be achieved with increased ability compared to conventional strategies since the “recessed” area 202D may now comprise the fill material 223D, which in turn ensures an improved surface topography upon forming the gate electrode structure 230 and forming the protective liner 234. Furthermore, upon forming the gate electrode structure 230, for instance on the basis of process techniques as described above with reference to the semiconductor device 100, in particular any portions of the gate electrode structure 230 formed adjacent to the initially recessed area 202D may result in significantly reduced patterning related irregularities, such as the creation of any remaining portions of the sensitive materials 231, 232A, thereby also enabling a reliable encapsulation of the resulting gate electrode structure 230 by the liner 234. Moreover, due to the reduced or substantially completely avoided recessing in the area 202D, the encapsulation of the gate electrode structure 230 may be preserved during any further highly critical process steps, such as the incorporation of a strain-inducing semiconductor alloy, as is for instance described above with reference to the device 100, which may conventionally result in the exposure of the materials 231 and/or 232A, which in turn may cause severe gate failures, as discussed above.

In some illustrative embodiments, the gate electrode structure 230 may be formed on the basis of a threshold voltage adjusting semiconductor alloy 202E, for instance in the form of a silicon/germanium alloy, if a corresponding adaptation of the electronic characteristics is required, for instance for adjusting appropriate threshold voltage values for different types of transistors. In this case, after providing the fill material 223D and prior to forming the gate electrode structure 230, the active region 202A may be recessed, for instance on the basis of any appropriate etch strategy, and subsequently the material 202E may be grown on the basis of selective epitaxial growth techniques. Consequently, upon recessing the active region 202A, the corresponding recess may be bordered by the material 223D, which may thus provide superior growth conditions upon depositing the material 202E. That is, due to the presence of the fill material 223D in the area 202D, a lateral growth of the material 220E may be substantially avoided, thereby obtaining superior growth conditions within the entire active region 202A, which in turn results in superior uniformity of the transistor characteristics, which strongly depend on the material composition and the layer thickness of the semiconductor alloy 202E.

FIG. 2h schematically illustrates the semiconductor device 200 in a further advanced manufacturing stage. As shown, a transistor 250 may be formed in and above the active region 202A and may comprise a gate electrode structure 230A, while a further gate electrode structure 230C may be formed above the trench isolation region 202C in close proximity to the active region 202A, for instance according to a device configuration as is previously discussed with reference to FIGS. 1a and 1b when referring to the semiconductor device 100. The gate electrode structures 230A, 230C may have basically the same configuration and may comprise a gate dielectric material 231, for instance in the form of a high-k dielectric material, followed by the electrode material 232A and the further electrode material 232. As discussed above, a length of the gate electrode structures 230A, 230C, i.e., in FIG. 2h, the horizontal extension of the electrode materials 232A, may be 50 nm and less. Moreover, as shown, the liner material 234 may still reliably cover any sidewall areas of the sensitive materials 231, 232A. Additionally, a spacer structure 235 having any appropriate configuration may be formed on the liner 234. Furthermore, the transistor 250 may comprise drain and source regions 251 formed in the active region 202A in accordance with the overall device requirements.

In some illustrative embodiments, the active region 202A may comprise a strain-inducing semiconductor material 252A, which may be formed by using process techniques as discussed above with reference to the semiconductor device 100, wherein, after the corresponding cavity etch process and the selective deposition of the material 252A, still a reliable encapsulation of the gate electrode structures 230A, 230C may be achieved. Furthermore, as described with reference to FIG. 2g, the threshold voltage adjusting semiconductor material 202E may be provided in the active region 202A and may thus represent a part thereof.

The semiconductor device 200 as shown in FIG. 2h may be formed on the basis of any appropriate process strategy after patterning the gate electrode structures 230A, 230C, as is described above, which may include the formation of appropriate spacer elements (not shown) which may be used as an implantation mask for forming a part of the drain and source regions 251. Thereafter, the spacer structure 235 may be completed and may be used as an implantation mask for incorporating further drain and source dopant species, followed by any anneal processes in order to adjust the final vertical and lateral dopant profile. Thereafter, the processing may be continued, for instance, by forming metal silicide in the drain and source regions 251, and in the electrode material 232, followed by the formation of a contact level, i.e., the deposition of dielectric materials and patterning the same so as to form contact openings, which may be substantially filled with any appropriate conductive material.

As a result, the present disclosure provides manufacturing techniques and semiconductor devices in which trench isolation regions may be formed on the basis of well-established process techniques, wherein any divots or recessed areas may be reduced in depth or may be completely filled in a subsequent process sequence prior to forming sophisticated gate electrode structures. Consequently, encapsulation of high-k metal gate electrode structures may be achieved with superior reliability, thereby avoiding or at least significantly reducing gate failures or shifts of transistor characteristics, which are conventionally caused by insufficient encapsulation and thus protection of sensitive gate materials.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a trench isolation region in a semiconductor layer of a semiconductor device, said trench isolation region laterally delineating an active region in said semiconductor layer;
forming a fill material selectively in a recessed area of said trench isolation region; and
forming a gate electrode structure on said active region and said trench isolation region including said fill material.

2. The method of claim 1, wherein forming a gate electrode structure comprises forming a gate insulation layer so as to include a high-k dielectric material, forming a metal-containing electrode material above said gate insulation layer and forming an encapsulating liner on exposed surface areas of at least said gate insulation layer and said metal-containing electrode material.

3. The method of claim 1, wherein forming said trench isolation region comprises depositing a dielectric material in an isolation trench and removing an excess portion of said dielectric material by using a hard mask material as a stop material.

4. The method of claim 3, further comprising removing said hard mask material prior to forming said cap layer.

5. The method of claim 3, further comprising performing an anneal process prior to forming said fill material so as to densify said dielectric material.

6. The method of claim 1, wherein forming said fill material comprises forming a cap layer above said trench isolation region so as to overfill said recessed area in said trench isolation region.

7. The method of claim 6, further comprising annealing said cap layer.

8. The method of claim 7, further comprising removing an excess portion of said cap layer.

9. The method of claim 7, wherein removing an excess portion of said cap layer comprises performing a wet chemical etch process that is selective with respect to said active region.

10. The method of claim 6, wherein forming said fill material further comprises forming a stop liner above said active region and said trench isolation region prior to forming said cap layer.

11. The method of claim 3, wherein forming said fill material comprises depositing an insulating material having substantially the same material composition as said dielectric material.

12. The method of claim 1, further comprising forming a semiconductor alloy on said active region prior to forming said gate electrode structure.

13. The method of claim 12, wherein forming said semiconductor alloy comprises recessing said active region and selectively depositing said semiconductor alloy in said recess.

14. A method, comprising:
forming a trench isolation region in a semiconductor layer of a semiconductor device so as to laterally delineate an active region, said trench isolation region comprising a recessed area adjacent to said active region;
reducing a depth of said recessed area of said trench isolation region; and
forming a gate electrode structure on said trench isolation region, said gate electrode structure comprising a high-k dielectric material.

15. The method of claim 14, wherein reducing a depth of said recessed area comprises filling a silicon oxide material in said recessed area.

16. The method of claim 15, further comprising annealing said silicon oxide material so as to densify said silicon oxide material.

17. The method of claim 16, wherein annealing said silicon oxide material comprises exposing said silicon oxide material to a temperature of 800° C. and higher and establishing an atmosphere containing at least one of oxygen and nitrogen.

18. The method of claim 15, wherein reducing a depth of said recessed area comprises forming a stop liner and a fill material in said recessed area.

19. A semiconductor device, comprising:
a trench isolation region laterally delineating an active region in a semiconductor layer, said trench isolation region comprising a first dielectric material and a second dielectric material locally formed adjacent to said active region; and
a gate electrode structure formed on a channel area of said active region, said gate electrode structure comprising a material system comprising a high-k dielectric material and a metal-containing electrode material, said gate electrode structure further comprising a protective liner formed on sidewalls of said high-k dielectric material and said metal-containing electrode material.

20. The semiconductor device of claim 19, wherein said first dielectric material and at least a portion of said second dielectric material have the same stoichiometric composition.

21. The semiconductor device of claim 18, wherein said second dielectric material comprises a stop liner and a fill layer formed on said etch stop liner.
